(19) United States
(12) Patent Application Publication
(10) Pub. No.: US 2008/0194049 A1
(43) Pub. Date: Aug. 14, 2008

(54) Method for making a light emitting device

(75) Inventors: Dong-Sing Wuu, Taichung City (TW); Ray-Hua Horng, Taichung City (TW); Cheng-Chung Chiang, Taichung City (TW)

Correspondence Address: DAVIDSON BERQUIST JACKSON & GOWDEY LLP, 4300 WILSON BLVD., 7TH FLOOR, ARLINGTON, VA, 22203, US

(73) Assignee: Dong-Sing Wuu, Taichung City (TW)

(21) Appl. No.: 11/812,418

(22) Filed: Jun. 19, 2007

(30) Foreign Application Priority Data
Feb. 12, 2007 (TW) 096105079

(51) Int. Cl. H01L 33/00

(52) U.S. Cl. 438/26; 257/E33.001

(57) ABSTRACT

A method for making a light emitting device includes: (a) preparing a chip-mounting board having a conductive surface; (b) mounting a plurality of vertical-feedthrough-LED chips on the conductive surface of the chip-mounting board; (c) forming a photoresist layer that cooperates with the chip-mounting board to enclose the vertical-feedthrough-LED chips; (d) patterning the photoresist layer by photolithography techniques to form a plurality of holes in the photoresist layer in such a manner that each of the holes exposes an electrode of a respective one of the vertical-feedthrough-LED chips; and (e) forming a conductive layer that covers the patterned photoresist layer and the vertical-feedthrough-LED chips.

### CROSS-REFERENCE TO RELATED APPLICATION

This application claims priority of Taiwanese Application No. 096105079, filed on Feb. 12, 2007.

### BACKGROUND OF THE INVENTION

1. Field of the Invention

This invention relates to a method for making a light emitting device, more particularly to a method involving isolating vertical-feedthrough-LED chips on a chip-mounting board using a patterned photoresist for making a light emitting device.

2. Description of the Related Art

U.S. Pat. No. 7,128,438 discloses a light display structure that includes strip-like first and second conductors, a plurality of LED chips disposed between and in electrical contact with the first and second conductors, and spacers disposed between the first and second conductors and defining apertures, each of which receives a respective one of the LED chips. The spacers are formed from a strip of a molded polymer.

The aforesaid conventional light display structure is disadvantageous in that the manufacturing process thereof is relatively complicated.

### SUMMARY OF THE INVENTION

Therefore, the object of the present invention is to provide a method for making a light emitting device that can overcome the aforesaid drawback associated with the prior art.

According to this invention, there is provided a method for making a light emitting device. The method comprises: (a) preparing a chip-mounting board having a conductive surface; (b) mounting a plurality of vertical-feedthrough-LED chips on the conductive surface of the chip-mounting board such that a first electrode of each of the vertical-feedthrough-LED chips is in electrical contact with the conductive surface; (c) forming a photoresist layer that cooperates with the chip-mounting board to enclose the vertical-feedthrough-LED chips; (d) patterning the photoresist layer by photolithography techniques to form a plurality of holes in the photoresist layer in such a manner that each of the holes exposes at least a portion of a second electrode of a respective one of the vertical-feedthrough-LED chips; and (e) forming a conductive layer that covers the patterned photoresist layer and the exposed portions of the second electrodes of the vertical-feedthrough-LED chips, which are exposed from the holes in the photoresist layer.

### BRIEF DESCRIPTION OF THE DRAWINGS

Other features and advantages of the present invention will become apparent in the following detailed description of the preferred embodiment of this invention, with reference to the accompanying drawings, in which:

FIGS. 1 to 8 are fragmentary schematic views illustrating consecutive steps of the preferred embodiment of a method for making a light emitting device according to this invention; and

FIG. 9 is a fragmentary schematic side view illustrating how a light beam from an LED chip can be redirected by two slanted surfaces formed on a chip-mounting board of the light emitting device of this invention.

### DETAILED DESCRIPTION OF THE PREFERRED EMBODIMENT

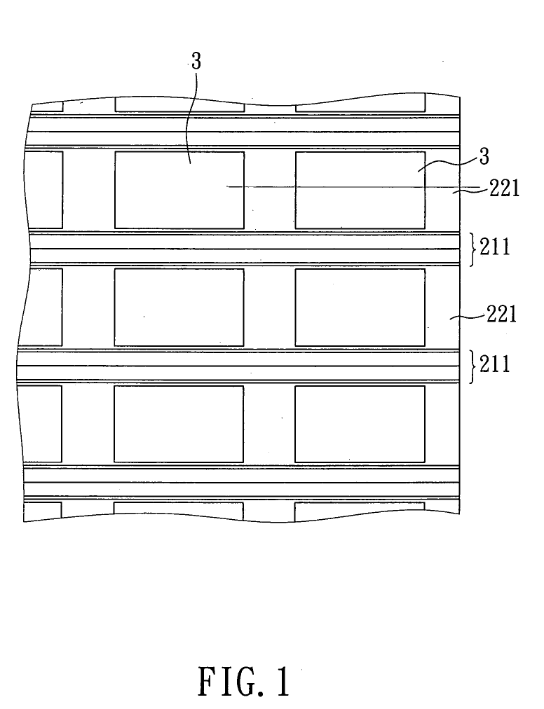

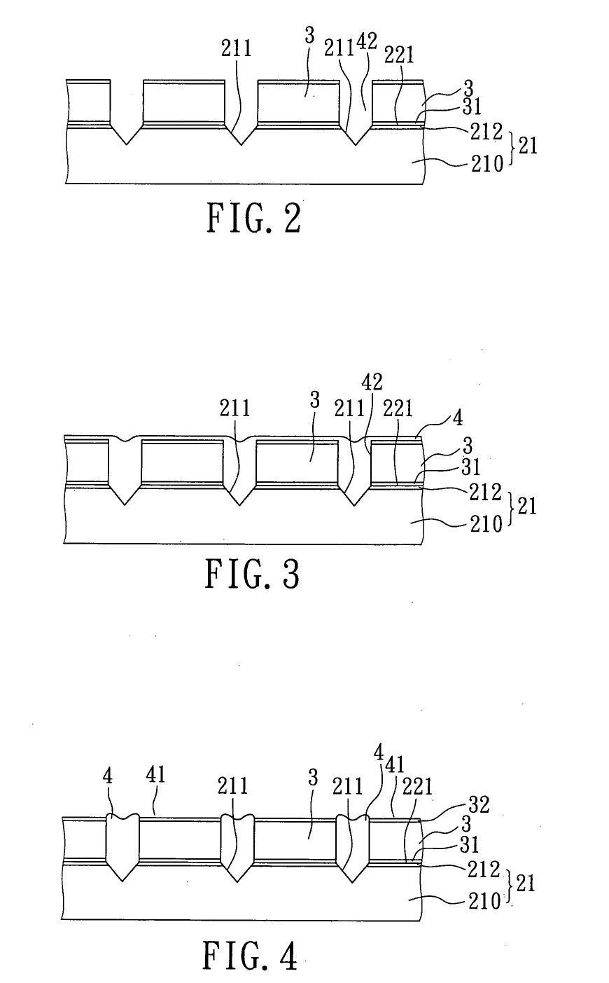

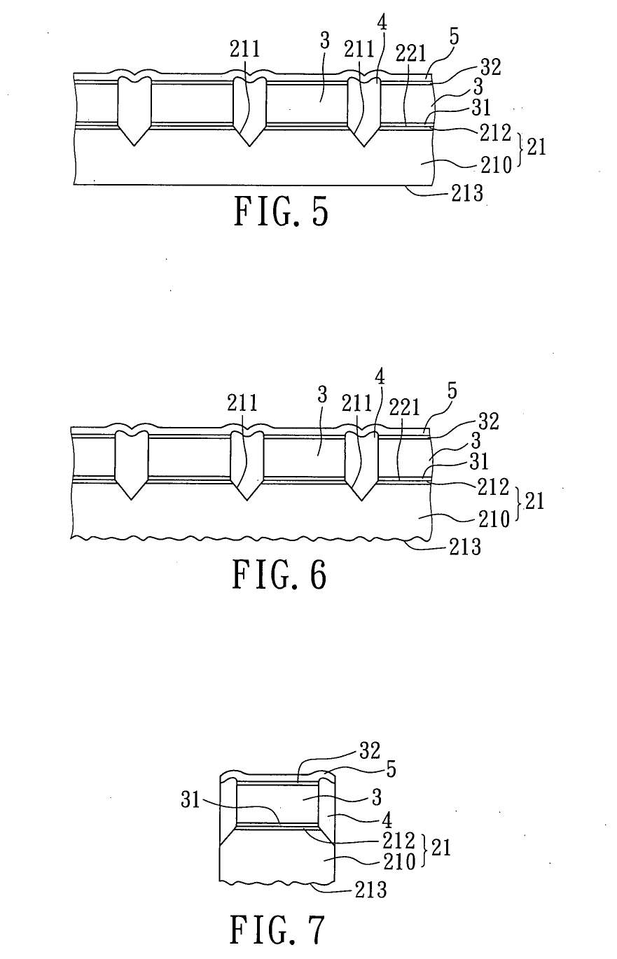

FIGS. 1 to 8 illustrate consecutive steps of the preferred embodiment of a method for making a light emitting device according to this invention. The method includes the steps of: (a) preparing a chip-mounting board 21 having a conductive surface 221 (see FIG. 1); (b) mounting a plurality of vertical-feedthrough-LED chips 3, on the conductive surface 221 of the chip-mounting board 21 such that a first electrode 31 of each of the vertical-feedthrough-LED chips 3 is in electrical contact with the conductive surface 221 (see FIG. 2); (c) forming a photoresist layer 4 that cooperates with the chip-mounting board 21 to enclose the vertical-feedthrough-LED chips 3 (see FIG. 3); (d) patterning the photoresist layer 4 by photolithography techniques to form a plurality of holes 41 in the photoresist layer 4 in such a manner that each of the holes 41 exposes at least a portion of a second electrode 32 of a respective one of the vertical-feedthrough-LED chips 3 (see FIG. 4); and (e) forming a conductive layer 5 that covers the patterned photoresist layer 4 and the exposed portions of the second electrodes 32 of the vertical-feedthrough-LED chips 3 (see FIG. 5).

In this preferred embodiment, the chip-mounting board 21 is composed of a supporting substrate 210 and a conductive film 212 formed on the supporting substrate 210 and defining the conductive surface 221 of the chip-mounting board 21.

The method further includes a step of forming a plurality of parallel strip-like cleaving grooves 211 in the chip-mounting board 21 after step (a) and prior to step (b) (see FIG. 2). The photoresist layer 4 formed in step (c) fills the strip-like cleaving grooves 211 and gaps 42 among the vertical-feedthrough-LED chips 3, and covers the second electrodes 32 of the vertical-feedthrough-LED chips 3 (see FIG. 3). The vertical-feedthrough-LED chips 3 are grouped into a plurality of columns, each of which is disposed between two adjacent ones of the strip-like cleaving grooves 211.

The method further includes a step of breaking an assembly of the conductive layer 5, the photoresist layer 4, the vertical-feedthrough-LED chips 3, and the chip-mounting board 21 along the strip-like cleaving grooves 211 after step (e) so as to form a plurality of light bars (see FIG. 7), each of which includes a respective one of the columns of the vertical-feedthrough-LED chips 3. The light bars thus formed are suitable for applications, such as a high dpi scanning copy machine.

The method can optionally further include a step of roughening a back surface 213 of the chip-mounting board 21 (see FIG. 6), which is disposed opposite to the conductive surface 221, so as to provide a light scattering effect and to reduce undesired total reflection.

In this embodiment, the chip-mounting board 21 and the first electrode 31 of each of the vertical-feedthrough-LED chips 3 are transparent, the photoresist layer 4 is made from a negative photoresist material, and the second electrode 32 of each of the vertical-feedthrough-LED chips 3 is reflective so that a back-side exposure can be conducted in step (d) in such a manner that a portion of the photoresist layer 4, which fills the strip-like cleaving grooves 211 and the gaps 42 among the vertical-feedthrough-LED chips 3, is exposed to a radiation through the back surface 213 of the chip-mounting board 21, and that the remainder of the photoresist layer 4, which is covered by the second electrodes 32 of the vertical-feedthrough-LED chips 3, remains unexposed and is removed subsequently to form the holes 41. Alternatively, the photoresist layer 4 can be made from a positive photoresist material. As such, a front-side exposure is conducted using a mask to expose the portion of the photoresist layer 4 to a radiation.

The supporting substrate 210 of the chip-mounting board 21 is preferably made from a rigid material selected from the group consisting of glass, quartz, a diffuser plate, a thick plastic plate, and the like. Each of the strip-like cleaving grooves 211 formed in the chip-mounting board 21 is preferably defined by a V-shaped groove-defining wall. Preferably, the ratio of the depth of each of the strip-like cleaving grooves 211 to the layer thickness of the chip-mounting board 21 ranges from 1:4 to 4:5 so as to facilitate the breaking of the chip-mounting board 21.

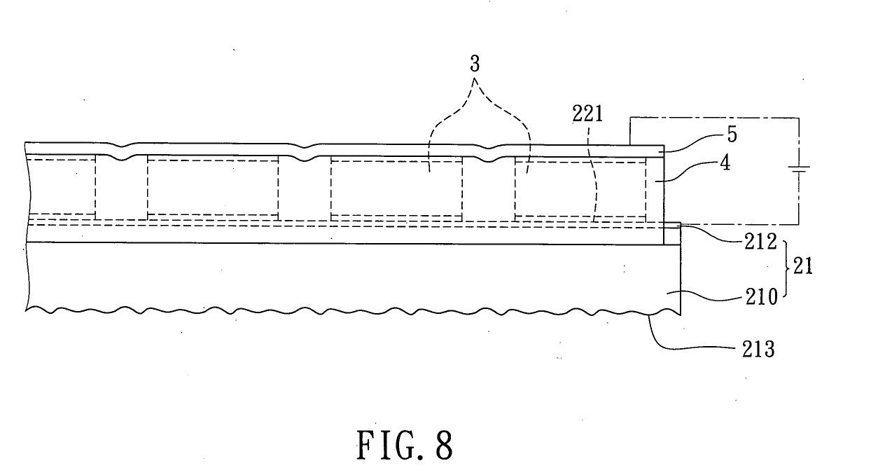

As illustrated in FIG. 8, each of the light bars thus formed can be connected electrically to a power source 6 through the conductive surface 221 of the chip-mounting board 21 and the conductive layer 5.

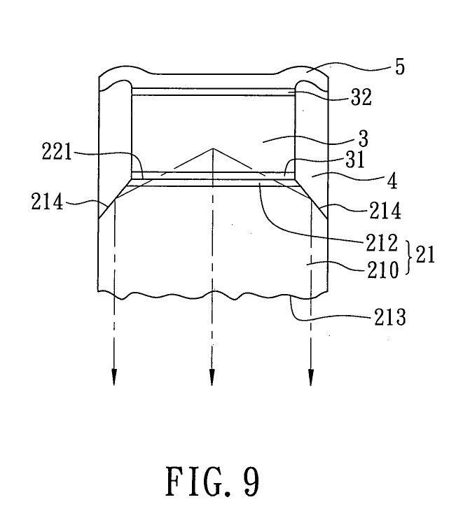

Referring to FIG. 9, formation of each of the strip-like cleaving grooves 211 results in formation of two opposite slanted surfaces 214 on the chip-mounting board 21 on each of the light bars. The slanted surfaces 214 of the chip-mounting board 21 can redirect the light from the vertical-feedthrough-LED chips 3. Hence, by adjusting the angle of each of the slanted surfaces 214 of the chip-mounting board 21 relative to a normal direction of the chip-mounting board 21, the light from the vertical-feedthrough-LED chips 3 can be redirected to a desired direction.

To achieve a white light, the vertical-feedthrough-LED chips 3 of each of the light bars thus formed can be composed of red-light-emitting diodes, green-light-emitting diodes, and blue-light-emitting diodes. Alternatively, the back surface 213 of the chip-mounting board 21 can be coated with a phosphor material to convert the wavelength of the light from the vertical-feedthrough-LED chips 3 so as to achieve the white light.

It is noted that the supporting substrate 210 of the chip-mounting board 21 can also be made from a conductive material, such as a metallic plate. As such, formation of the conductive film 212 can be dispensed with. When a stainless steel plate is used as the chip-mounting board 21, formation of the strip-like cleaving grooves 211 can be conducted using wire cutting techniques.

The merits of the method of this invention will become apparent with reference to the following Example.

### EXAMPLE

In this example, an indium tin oxide (ITO) film was deposited on a glass substrate having a layer thickness of about 700 μm so as to form the chip-mounting board 21 which was subsequently cut to form a plurality of the strip-like cleaving grooves 211, each of which has a depth of about 350 μm. A plurality of the vertical-feedthrough-LED chips 3 were then mounted on the chip-mounting board 21. The assembly was then subjected to a coating operation using a spinning coater for forming the photoresist layer 4 on the assembly, which was subsequently subjected to an exposing operation using a back-side exposure system. The exposed portion of the photoresist layer 4 was hardened, while the unexposed portion of the photoresist layer 4, which was disposed on the vertical-feedthrough-LED chips 3, was then removed to form the holes 41 in the photoresist layer 4. A conductive layer 5 was then formed on the vertical-feedthrough-LED chips 3 and the remainder portion of the photoresist layer 4. The assembly thus formed was then subjected to a breaker to break the same along the strip-like cleaving grooves 211 so as to form the light bars.

By virtue of the processes of forming the photoresist layer 4 and the conductive layer 5, the method for making the light emitting device of this invention is simpler than the aforesaid conventional method. In addition, the size of the light emitting device formed by the method of this invention can be reduced as compared to the aforesaid conventional light emitting device.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A method for making a light emitting device comprising:
(a) preparing a chip-mounting board having a conductive surface;
(b) mounting a plurality of vertical-feedthrough-LED chips on the conductive surface of the chip-mounting board such that a first electrode of each of the vertical-feedthrough-LED chips is in electrical contact with the conductive surface;
(c) forming a photoresist layer that cooperates with the chip-mounting board to enclose the vertical-feedthrough-LED chips;
(d) patterning the photoresist layer by photolithography techniques to form a plurality of holes in the photoresist layer in such a manner that each of the holes exposes at least a portion of a second electrode of a respective one of the vertical-feedthrough-LED chips; and
(e) forming a conductive layer that covers the patterned photoresist layer and the exposed portions of the second electrodes of the vertical-feedthrough-LED chips, which are exposed from the holes in the photoresist layer.

2. The method of claim 1, further comprising forming a plurality of parallel strip-like cleaving grooves in the chip-mounting board after step (a) and prior to step (b), the vertical-feedthrough-LED chips being grouped into a plurality of columns, each of which is disposed between two adjacent ones of the strip-like cleaving grooves, the method further comprising breaking an assembly of the conductive layer, the photoresist layer, the vertical-feedthrough-LED chips, and the chip-mounting board along the strip-like cleaving grooves after step (e) so as to form a plurality of light bars, each of which includes a respective one of the columns of the vertical-feedthrough-LED chips.

3. The method of claim 2, wherein the chip-mounting board and the first electrode of each of the vertical-feedthrough-LED chips are transparent, the photoresist layer is made from a negative photoresist material, and the second electrode of each of the vertical-feedthrough-LED chips is reflective, and wherein a back-side exposure is conducted in step (d) in such a manner that a portion of the photoresist layer, which fills the strip-like cleaving grooves and gaps among the vertical-feedthrough-LED chips, is exposed to a radiation through a back surface of the chip-mounting board which is disposed opposite to the conductive surface, and that the remainder of the photoresist layer, which is covered by the second electrodes of the vertical-feedthrough-LED chips, remains unexposed and is removed subsequently to form the holes.

4. The method of claim 1, wherein the chip-mounting board is made from a material selected from the group consisting of glass and quartz.

5. The method of claim 2, wherein each of the strip-like cleaving grooves is defined by a V-shaped groove-defining wall.

6. The method of claim 5, wherein the ratio of the depth of each of the strip-like cleaving grooves to the layer thickness of the chip-mounting board ranges from 1:4 to 4:5.

7. The method of claim 3, further comprising roughening the back surface of the chip-mounting board.

8. The method of claim 1, wherein the chip-mounting board is formed by forming a conductive film on a supporting substrate, the conductive film defining the conductive surface of the chip-mounting board.

9. The method of claim 8, wherein the supporting substrate is made from glass, and the conductive film is made from indium tin oxide.
